(19) United States
(12) Patent Application Publication
(10) Pub. No.: US 2006/0186396 A1
(43) Pub. Date: Aug. 24, 2006

(54) Optical element and method for manufacturing the same

(75) Inventor: Tetsuo Hiramatsu, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/348,469

(22) Filed: Feb. 7, 2006

(30) Foreign Application Priority Data
Feb. 18, 2005 (JP) 2005-042120

(51) Int. Cl. H01L 29/06

(52) U.S. Cl. 257/9

(57) ABSTRACT

An optical element has: an emission section including a first semiconductor layer of a first conductivity type, an active layer formed above the first semiconductor layer and a second semiconductor layer of a second conductivity type formed above the active layer; an interlayer dielectric layer; and an electrostatic breakdown prevention section including a first conductive layer formed above the interlayer dielectric layer, a second conductive layer formed above the interlayer dielectric layer, and an insulating member formed between the first conductive layer and the second conductive layer, and at a side of the first conductive layer and at a side of the second conductive layer, wherein the first conductive layer is electrically connected to the first semiconductor layer, the second conductive layer is electrically connected to the second semiconductor layer, at least one of the first conductive layer and the second conductive layer has a protruded section, the emission section and the electrostatic breakdown prevention section are electrically connected in parallel with each other, and a dielectric breakdown voltage of the electrostatic breakdown prevention section is greater than a drive voltage of the emission section and smaller than an electrostatic breakdown voltage of the emission section.

The entire disclosure of Japanese Patent Application No. 2005-042120, filed Feb. 18, 2005 is expressly incorporated by reference herein.

### BACKGROUND

1. Technical Field

The present invention relates to optical elements and methods for manufacturing the same.

2. Related Art

A surface-emitting type semiconductor laser has a smaller device volume compared to an ordinary edge-emitting type semiconductor laser, such that the electrostatic breakdown voltage of the device itself is low. For this reason, the device may be damaged by static electricity caused by a machine or an operator in a mounting process. A variety of measures are usually implemented in a mounting process to remove static electricity, but these measures have limitations.

For example, Japanese laid-open patent application JP-A-2004-6548 describes a technology to compose a capacitance element by laminating an insulating film and a metal film wherein the capacitance element serves as a breakdown voltage element. In this case, it may take a long time for laminating layers to form a desired capacitance element as an insulating film and a metal film are laminated.

### SUMMARY

In accordance with an advantage of some aspects of the invention, electrostatic breakdown can be prevented and reliability can be improved with respect to optical elements and methods for manufacturing the same.

In accordance with an embodiment of the invention, an optical element has an emission section including a first semiconductor layer of a first conductivity type, an active layer formed above the first semiconductor layer and a second semiconductor layer of a second conductivity type formed above the active layer, an interlayer dielectric layer, and an electrostatic breakdown prevention section including a first conductive layer formed above the interlayer dielectric layer, a second conductive layer formed above the interlayer dielectric layer, and an insulating member formed between the first conductive layer and the second conductive layer and at a side of the first conductive layer and at a side of the second conductive layer, wherein the first conductive layer is electrically connected to the first semiconductor layer, the second conductive layer is electrically connected to the second semiconductor layer, at least one of the first conductive layer and the second conductive layer has a protruded section, the emission section and the electrostatic breakdown prevention section are electrically connected in parallel with each other, and a dielectric breakdown voltage of the electrostatic breakdown prevention section is greater than a drive voltage of the emission section and smaller than an electrostatic breakdown voltage of the emission section.

According to the optical element, even when a voltage that may cause an electrostatic breakdown is impressed to the emission section, a current flows to the electrostatic breakdown prevention section that is connected in parallel with the emission section. By this, the electrostatic breakdown voltage resistance of the optical element can be considerably improved. Accordingly, an electrostatic breakdown of the device by static electricity in a mounting process or the like can be prevented, such that its handling can be well facilitated, and its reliability can be improved.

It is noted that, in the embodiments of the invention, another specific element (hereafter referred to as “B”) that is formed above a specific element (hereafter referred to as “A”), includes B that is formed directly on A, and B that is formed above A through another element on A. Also, in the invention, forming B above A includes a case of forming B directly on A, and a case of forming B above A through another element on A.

Also, in the embodiments of the invention, an “electrostatic breakdown voltage of an emission section” means a minimum voltage by which an electrostatic breakdown occurs at the emission section.

In the optical element in accordance with an aspect of the embodiment, the electrostatic breakdown voltage of the emission section may concern a reverse bias.

In the optical element in accordance with an aspect of the embodiment, the first conductive layer and the second conductive layer may be electrodes for driving the emission section.

In the optical element in accordance with an aspect of the embodiment, the emission section may function as a surface-emitting type semiconductor laser, and the first semiconductor layer and the second semiconductor layer may be mirrors.

In accordance with another embodiment of the invention, a second optical element has a photodetection section including a first semiconductor layer of a first conductivity type, a photoabsorption layer formed above the first semiconductor layer and a second semiconductor layer of a second conductivity type formed above the photoabsorption layer, an interlayer dielectric layer, and an electrostatic breakdown prevention section including a first conductive layer formed above the interlayer dielectric layer, a second conductive layer formed above the interlayer dielectric layer, and an insulating member formed between the first conductive layer and the second conductive layer, and at a side of the first conductive layer and at a side of the second conductive layer, wherein the first conductive layer is electrically connected to the first semiconductor layer, the second conductive layer is electrically connected to the second semiconductor layer, at least one of the first conductive layer and the second conductive layer has a protruded section, the photodetection section and the electrostatic breakdown prevention section are electrically connected in parallel with each other, and a dielectric breakdown voltage of the electrostatic breakdown prevention section is greater than a drive voltage of the photodetection section and smaller than an electrostatic breakdown voltage of the photodetection section.

It is noted that, in the embodiments of the invention, a “photoabsorption layer” refers to a concept including a depletion layer.

Also, in the embodiments of the invention, an “electrostatic breakdown voltage of a photodetection section” means a minimum voltage by which an electrostatic breakdown occurs at the photodetection section.

In accordance with an aspect of the embodiment of the invention, the optical element may have a substrate, and the first semiconductor layer and the interlayer dielectric layer may be formed above the substrate.

In accordance with an aspect of the embodiment of the invention, the optical element may have a first electrode formed between the first semiconductor layer and the first conductive layer, and a second electrode formed between the second semiconductor layer and the second conductive layer.

In the optical element in accordance with an aspect of the embodiment of the invention, the protruded section may have a pointed tip.

In the optical element in accordance with an aspect of the embodiment of the invention, the protruded section may have a flat tip.

In the optical element in accordance with an aspect of the embodiment of the invention, the interlayer dielectric layer may define a hole, and a tip of the protruded section may be formed above the hole, and not in contact with the interlayer dielectric layer.

In the optical element in accordance with an aspect of the embodiment of the invention, the insulating member has an upper surface that may be a convex curved surface.

A first method for manufacturing an optical element in accordance with an embodiment of the invention includes the steps of forming a semiconductor multilayer film, including forming a first semiconductor layer of a first conductivity type above a substrate, forming an active layer above the first semiconductor layer, and forming a second semiconductor layer of a second conductivity type above the active layer, patterning the semiconductor multilayer film to form an emission section that includes the first semiconductor layer, the active layer and the second semiconductor layer, forming an interlayer dielectric layer above the substrate, forming a first conductive layer above the interlayer dielectric layer, forming a second conductive layer above the interlayer dielectric layer, and forming an insulating member between the first conductive layer and the second conductive layer, and at a side of the first conductive layer and at a side of the second conductive layer, wherein the first conductive layer is arranged to electrically connect to the first semiconductor layer, the second conductive layer is arranged to electrically connect to the second semiconductor layer, at least one of the first conductive layer and the second conductive layer is formed to have a protruded section, an electrostatic breakdown prevention section including the first conductive layer, the second conductive layer and the insulating member is arranged to electrically connect in parallel with the emission section, and a dielectric breakdown voltage of the electrostatic breakdown prevention section is set to be greater than a drive voltage of the emission section and smaller than an electrostatic breakdown voltage of the emission section.

A second method for manufacturing an optical element in accordance with an embodiment of the invention includes the steps of forming a semiconductor multilayer film, including forming a first semiconductor layer of a first conductivity type above a substrate, forming a photoabsorption layer above the first semiconductor layer, and forming a second semiconductor layer of a second conductivity type above the photoabsorption layer, patterning the semiconductor multilayer film to form a photodetecting section that includes the first semiconductor layer, the photoabsorption layer and the second semiconductor layer, forming an interlayer dielectric layer above the substrate, forming a first conductive layer above the interlayer dielectric layer, forming a second conductive layer above the interlayer dielectric layer, and forming an insulating member between the first conductive layer and the second conductive layer, and at a side of the first conductive layer and at a side of the second conductive layer, wherein the first conductive layer is arranged to electrically connect to the first semiconductor layer, the second conductive layer is arranged to electrically connect to the second semiconductor layer, at least one of the first conductive layer and the second conductive layer is formed to have a protruded section, an electrostatic breakdown prevention section including the first conductive layer, the second conductive layer and the insulating member is arranged to electrically connect in parallel with the photodetecting section, and a dielectric breakdown voltage of the electrostatic breakdown prevention section is set to be greater than a drive voltage of the photodetecting section and smaller than an electrostatic breakdown voltage of the photodetecting section.

In the method for manufacturing an optical element in accordance with an aspect of the embodiment of the invention, the insulating member may be formed by using a droplet discharge method.

The method for manufacturing an optical element in accordance with an aspect of the embodiment of the invention may include forming a hole in the interlayer dielectric layer by etching after at least one of the step of forming the first conductive layer and the step of forming the second conductive layer, wherein a tip of the protruded section may be formed above the hole so as not to contact the interlayer dielectric layer.

### BRIEF DESCRIPTION OF THE DRAWINGS

FIG. 1 is a cross-sectional view schematically showing an optical element in accordance with a first embodiment of the invention.

FIG. 2 is a plan view schematically showing the optical element in accordance with the first embodiment of the invention.

FIG. 3 is a circuit diagram of the optical element in accordance with the first embodiment.

FIG. 4 is a cross-sectional view schematically showing an optical element in accordance with another aspect of the first embodiment of the invention.

FIG. 5 is a plan view schematically showing the optical element in accordance with the other aspect of the first embodiment of the invention.

FIG. 6 is a cross-sectional view schematically showing an optical element in accordance with still another aspect of the first embodiment of the invention.

FIG. 7 is a cross-sectional view schematically showing a method for manufacturing an optical element in accordance with the first embodiment of the invention.

FIG. 8 is a cross-sectional view schematically showing the method for manufacturing an optical element in accordance with the first embodiment of the invention.

FIG. 9 is a cross-sectional view schematically showing the method for manufacturing an optical element in accordance with the first embodiment of the invention.

FIG. 10 is a cross-sectional view schematically showing the method for manufacturing an optical element in accordance with the first embodiment of the invention.

FIG. 11 is a cross-sectional view schematically showing the method for manufacturing an optical element in accordance with the first embodiment of the invention.

FIG. 12 is a cross-sectional view schematically showing an optical element in accordance with a modified example of the first embodiment of the invention.

FIG. 13 is a cross-sectional view schematically showing an optical element in accordance with a modified example of the first embodiment of the invention.

FIG. 14 is a cross-sectional view schematically showing an optical element in accordance with a modified example of the first embodiment of the invention.

FIG. 15 is a cross-sectional view schematically showing an optical element in accordance with a modified example of the first embodiment of the invention.

FIG. 16 is a plan view schematically showing an optical element in accordance with a modified example of the first embodiment of the invention.

FIG. 17 is a plan view schematically showing an optical element in accordance with a modified example of the first embodiment of the invention.

FIG. 18 is a plan view schematically showing an optical element in accordance with a modified example of the first embodiment of the invention.

### DESCRIPTION OF EXEMPLARY EMBODIMENTS

Preferred embodiments of the invention are described below with reference to the accompanying drawings.

1. First, an optical element 100 in accordance with an embodiment is described.

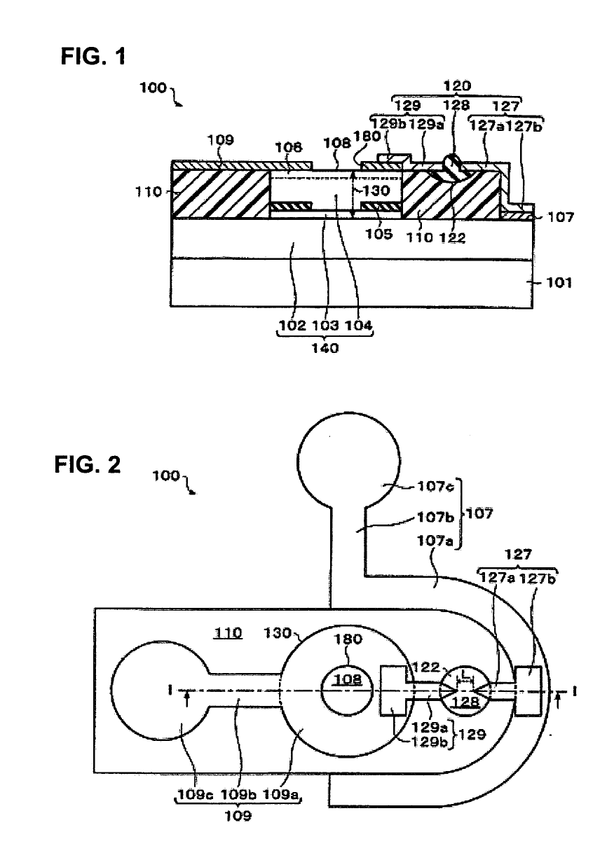

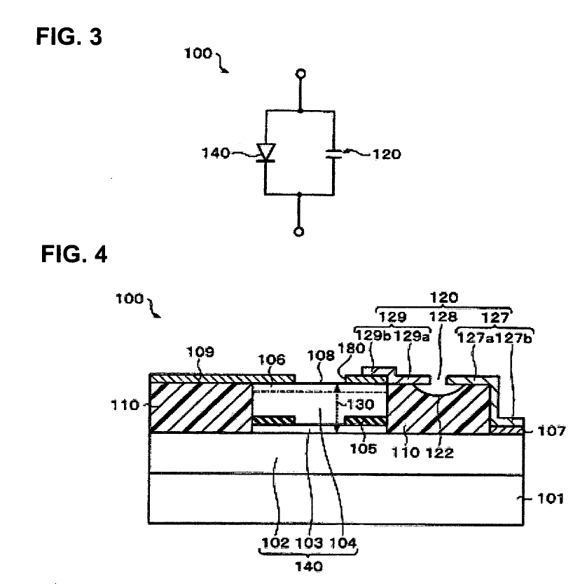

FIG. 1 is a cross-sectional view of the optical element 100 taken along a line I-I in FIG. 2, and FIG. 2 is a plan view schematically showing the optical element 100. FIG. 3 is a circuit diagram of the optical element 100.

The optical element 100 includes, as shown in FIG. 1 and FIG. 2, a substrate 101, an emission section 140, an interlayer dielectric layer 110, and a electrostatic breakdown prevention section 120. The example shown in FIG. 1 and FIG. 2 is described as to a case where the emission section 140 functions as a surface-emitting type semiconductor laser.

For example, a GaAs substrate of a first conductivity type (for example, n-type) can be used as the substrate 101. The substrate 101 supports the emission section 140 and the electrostatic breakdown prevention section 120. In other words, the emission section 140 and the electrostatic breakdown prevention section 120 are formed on a common substrate (on the same chip), and form a monolithic structure.

The emission section 140 is formed on the substrate 101. The emission section 140 includes a first semiconductor layer 102 of a first conductivity type (for example, n-type), an active layer 103 formed on the first semiconductor layer 102, and a second semiconductor layer 104 of a second conductivity type (for example, p-type) formed on the active layer 103. More concretely, the first semiconductor layer 102 is, for example, a distributed Bragg reflection type (DBR) mirror of 40 pairs of alternately laminated n-type Al_{0.9}Ga_{0.1}As layers and n-type Al_{0.15}Ga_{0.85}As layers. The active layer 103 has a multiple quantum well (MQW) structure in which quantum well structures each formed from, for example, a GaAs well layer and an Al_{0.3}Ga_{0.7}As barrier layer are laminated in three layers. The second semiconductor layer 104 is, for example, a DBR mirror of 25 pairs of alternately laminated p-type Al_{0.9}Ga_{0.1}As layers and p-type Al_{0.15}Ga_{0.85}As layers. An uppermost layer 106 of the second semiconductor layer 104 is a contact layer composed of a GaAs layer of the second conductivity type (p-type). The composition of each of the layers and the number of the layers composing the first semiconductor layer 102, the active layer 103 and the second semiconductor layer 104 are not particularly limited. The p-type second semiconductor layer 104, the active layer 103 that is not doped with an impurity and the n-type first semiconductor layer 102 form a pin diode.

The second semiconductor layer 104 and the active layer 103 among the emission section 140 form a columnar semiconductor deposited body (hereafter referred to as a “columnar section”) 130. The columnar section 130 may have a plane configuration that is, for example, a circular shape shown in FIG. 2.

Also, as shown in FIG. 1, at least one of the layers composing the second semiconductor layer 104 can be formed as an oxidized constricting layer 105. The oxidized constricting layer 105 is formed in a region near the active layer 103. As the oxidized constricting layer 105, for example, an oxidized AlGaAs layer can be used. The oxidized constricting layer 105 is a dielectric layer having an opening section. The oxidized constricting layer 105 is formed in a ring shape. More concretely, the oxidized constricting layer 105 is formed such that its cross-sectional shape, as being cut along a horizontal plane, is a ring shape that is concentric with the circular shape of the plane configuration of the columnar section 130.

A first electrode 107 is formed on an upper surface of the first semiconductor layer 102. The first electrode 107 is electrically connected to the first semiconductor layer 102. The first electrode 107 includes, as shown in FIG. 2, a contact section 107a, a lead-out section 107b and a pad section 107c. The first electrode 107 is in contact with the first semiconductor layer 102 at the contact section 107a. It is noted that the first electrode 107 can also be in contact with the first semiconductor layer 102 at the lead-out section 107b and the pad section 107c. The contact section 107a of the first electrode 107 has a plane configuration that is, for example, a halved ring shape having linearly extending end sections (U-shape) shown in FIG. 2. The contact section 107a is provided in a manner to surround the interlayer dielectric layer 110. The lead-out section 107b of the first electrode 107 connects the contact section 107a and the pad section 107c. The lead-out section 107b has, for example, a linear plane configuration shown in FIG. 2. The pad section 107c of the first electrode 107 is connected as an electrode pad to an external wiring or the like. The pad section 107c has a plane configuration that is, for example a circular shape shown in FIG. 2.

A second electrode 109 is formed on the columnar section 130 and the interlayer dielectric layer 110. The second electrode 109 is electrically connected to the second semiconductor layer 104. The second electrode 109 includes, as shown in FIG. 2, a contact section 109a, a lead-out section 109b and a pad section 109c. The second electrode 109 is in contact with the second semiconductor layer 104 at the contact section 109a. The contact section 109a of the second electrode 109 has a plane configuration that is, for example, a ring shape shown in FIG. 2. The contact section 109a has an opening section 180 over the columnar section 130. In other words, the opening section 180 defines a region where the contact section 109a is not provided on the upper surface of the second semiconductor layer 104. This region defines an emission surface 108 for emission of laser light. The emission surface 108 has a configuration that is, for example, a circular shape shown in FIG. 2. The lead-out section 109b of the second electrode 109 connects the contact section 109a and the pad section 109c. The lead-out section 109b has, for example, a linear plane configuration shown in FIG. 2. The pad section 109c of the second electrode 109 is connected as an electrode pad to an external wiring or the like. The pad section 109c has a plane configuration that is, for example, a circular shape shown in FIG. 2.

In the optical element 100 shown in FIG. 1 and FIG. 2, the first electrode 107 joins with the first semiconductor layer 102, and the second electrode 109 joins with the second semiconductor layer 104. A current is injected in the active layer 103 by the first electrode 107 and the second electrode 109.

The interlayer dielectric layer 110 is formed on the first semiconductor layer 102. The interlayer dielectric layer 110 is formed in a manner to surround the columnar section 130. The lead-out section 109b and the pad section 109c of the second electrode 109 are formed on the interlayer dielectric layer 110. The interlayer dielectric layer 110 electrically isolates the second electrode 109 from the first semiconductor layer 102. Also, protruded sections 127a and 129a of first and second conductive layers 127 and 129 and an insulating member 128, which are described below, are formed on the interlayer dielectric layer 110. A hole 122 is formed in the interlayer dielectric layer 110 on its upper surface side, and portions of the protruded sections 127a and 129a of the first and second conductive layers 127 and 129 and the insulating member 128 are formed over the hole 122. The hole 122 is not particularly limited to any shape, and may have a configuration defined by, for example, a spherical surface with a portion thereof removed, as shown in FIG. 1 and FIG. 2.

The electrostatic breakdown prevention section 120 includes a first conductive layer 127, an insulating member 128 and a second conductive layer 129. The first conductive layer 127 may include a protruded section 127a and an electrode contact section 127b. The first conductive layer 127 is formed at least on the interlayer dielectric layer 110. More concretely, the protruded section 127a of the first conductive layer 127 is formed on the interlayer dielectric layer 110. Also, as shown in FIG. 2, the first conductive layer 127 may be formed, for example, in a plane configuration with a line (line I-I) that divides in two the contact section 107a of the first electrode 107 as a center line thereof The protruded section 127a of the first conductive layer 127 protrudes, for example, toward the contact section 109a of the second electrode 109. The protruded section 127a has, for example, a linear plane configuration shown in FIG. 2. The tip of the protruded section 127a is pointed. In other words, side faces of the tip of the protruded section 127a define an acute angle. The tip of the protruded section 127a is formed above the hole 122 in the interlayer dielectric layer 110. Also, the tip of the protruded section 127a is not in contact with the interlayer dielectric layer 110, and a lower surface of the tip of the protruded section 127a is in contact with the insulating member 128. The electrode contact section 127b of the first conductive layer 127 is in contact with an upper surface of the first electrode 107. By this, the first conductive layer 127 is electrically connected to the first semiconductor layer 102 through the first electrode 107. The electrode contact section 127b is not limited to any particular shape, and may be, for example, in a rectangular shape shown in FIG. 2.

The second conductive layer 129 may include a protruded section 129a and an electrode contact section 129b. The second conductive layer 129 is formed at least on the interlayer dielectric layer 110. More concretely, the protruded section 129a of the second conductive layer 129 is formed on the interlayer dielectric layer 110. Also, as shown in FIG. 2, the second conductive layer 129 may be formed, for example, in a plane configuration with a line (line I-I) that divides in two the contact section 107a of the first electrode 107 as a center line thereof. The protruded section 129a of the second conductive layer 120 protrudes, for example, toward the contact section 107a of the first electrode 107. The protruded section 129a has, for example, a linear plane configuration shown in FIG. 2. The tip of the protruded section 129a is pointed. In other words, side faces of the tip of the protruded section 129a define an acute angle. The tip of the protruded section 129a is formed above the hole 122 in the interlayer dielectric layer 110. Also, the tip of the protruded section 129a is not in contact with the interlayer dielectric layer 110, and a lower surface of the tip of the protruded section 129a is in contact with the insulating member 128. The electrode contact section 129b of the second conductive layer 129 is in contact with an upper surface of the contact section 109a of the second electrode 109. By this, the second conductive layer 129 is electrically connected to the second semiconductor layer 104 through the second electrode 109. The electrode contact section 129b is not limited to any particular shape, and may be, for example, in a rectangular shape shown in FIG. 2.

The tip of the protruded section 127a of the first conductive layer 127 and the tip of the protruded section 129a of the second conductive layer 129 oppose to each other through the insulating member 128, as shown in FIG. 1 and FIG. 2. In other words, the insulating member 128 is formed at least at the side of the protruded section 127a of the first conductive layer 127 and at least at the side of the protruded section 129a of the second conductive layer 129. Also, for example, the first conductive layer 127, the insulating member 128 and the second conductive layer 129 may be aligned along the line (line I-I) that divides in two the contact section 107a of the first electrode 107, as shown in FIG. 2. The insulating member 128 is formed over the hole 122 in the interlayer dielectric layer 110. The insulating member 128 embeds the hole 122. In the process of forming an insulating member precursor 128a to be described below, the insulating member precursor 128a may be dammed up by, for example, the side faces of the protruded sections 127a and 129a of the first and second conductive layers 127 and 129, and may be dammed up by the edge of the hole 122, as shown in FIG. 2. Accordingly, the insulating member 128 is formed in a region inside the hole 122 where the protruded sections 127a and 129a are not formed. In this case, an upper surface of the insulating member 128 defines a convex curved surface. The insulating member 128 is not limited to any particular shape as long as the insulating member 128 is disposed between the tip of the protruded section 127a of the first conductive layer 127 and the tip of the protruded section 129a of the second conductive layer 129.

As the insulating member 128, a solid material, such as, for example, polyimide resin, epoxy resin, Si, GaAs, SiO₂, SiN or the like may be used. Also, a gas such as air may also be used as the insulating material 128, as shown in FIG. 4. The use of a solid material such as polyimide resin as the insulating material 128 can prevent an underfill material, which may be used when the optical element 100 is mounted, from entering the hole 122 and being placed between the protruded section 127a of the first conductive layer 127 and the protruded section 129a of the second conductive layer 129. Also, the insulating member 128 can be formed with any desired material and shape by the use of a solid material. It is noted that, if an underfill material that is used for the mounting process is used as the insulating material 128, a gas such as air may be used as the insulating material 128 before the mounting process, as shown in FIG. 4, and the underfill material can be disposed between the protruded section 127a of the first conductive layer 127 and the protruded section 129a of the second conductive layer 129 in the mounting process. By this, the process for manufacturing the optical element 100 can be simplified.

The dielectric breakdown voltage of the electrostatic breakdown prevention section 120 is set to be greater than the drive voltage of the emission section 140 and smaller than the electrostatic breakdown voltage of the emission section 140. By this, the emission operation of the emission section 140 can normally take place, and electrostatic breakdown of the emission section 140 can be prevented. More concretely, the following actions take place.

The emission section 140 and the electrostatic breakdown prevention section 120 are electrically connected in parallel with each other, as shown in the circuit diagram of FIG. 3. When the emission section 140 is driven, a forward bias voltage is impressed to the emission section 140, and the same voltage is impressed to the electrostatic breakdown prevention section 120. In this instance, the dielectric breakdown voltage of the electrostatic breakdown prevention section 120 may preferably be greater than the drive voltage of the emission section 140, so that current can flow only in the emission section 140. In other words, even when the drive voltage is impressed to the emission section 140, current does not flow to the electrostatic breakdown prevention section 120 because of the presence of the insulating member 128. As a result, the emission operation normally takes place at the emission section 140. Then, if a voltage that may cause an electrostatic breakdown is impressed to the emission section 140, the insulating member 128 has a dielectric breakdown, as the dielectric breakdown voltage of the electrostatic breakdown prevention section 120 is smaller than the minimum voltage (electrostatic breakdown voltage) that causes an electrostatic breakdown at the emission section 140. As a result, current flows to the electrostatic breakdown prevention section 120 connected in parallel with the emission section 140, whereby an electrostatic breakdown of the emission section 140 can be prevented.

The dielectric breakdown voltage of the electrostatic breakdown prevention section 120 can be set by, for example, adjusting the material of the insulating member 128, the distance L between the tip of the protruded section 127a of the first conductive layer 127 and the tip of the protruded section 129a of the second conductive layer 129, and the like. A value obtained by multiplying the distance L by a dielectric breakdown voltage per unit length Vᵤₙᵢₜ of the insulating member 128 can be used as the dielectric breakdown voltage V of the electrostatic breakdown prevention section 120, as follows.
V=L×Vᵤₙᵢₜ
Vᵤₙᵢₜ is about 30 kV/cm when the insulating member 128 is composed of air, about 7 kV/cm when it is composed of polyimide resin, about 6.5 kV/cm when it is composed of epoxy resin, about 300 kV/cm when it is composed of Si, about 400 kV/cm when it is composed of GaAs, about 6000 kV/cm when it is composed of SiO₂, and about 5000 kV/cm when it is composed of SiN. The drive voltage of the emission section 140 is, for example, about 3V. Also, the electrostatic breakdown voltage of the emission section 140 to a forward bias is normally greater than the electrostatic breakdown voltage of the emission section 140 to a reverse bias. More concretely, the electrostatic breakdown voltage of the emission section 140 to a forward bias is, for example, about 500V, and the electrostatic breakdown voltage to a reverse bias is, for example, about 300V. Accordingly, the dielectric breakdown voltage of the electrostatic breakdown prevention section 120 may preferably be set to be smaller than the electrostatic breakdown voltage of the emission section 140 to a reverse bias. By this, an electrostatic breakdown of the emission section 140 can be prevented against a forward bias or a reverse bias. For example, when the drive voltage of the emission section 140 is 3V, the electrostatic breakdown voltage to a reverse bias is 300V, and the insulating member 128 is composed of air, the distance L may be set in a range between 1.0 μm or greater and 100 μm or smaller.

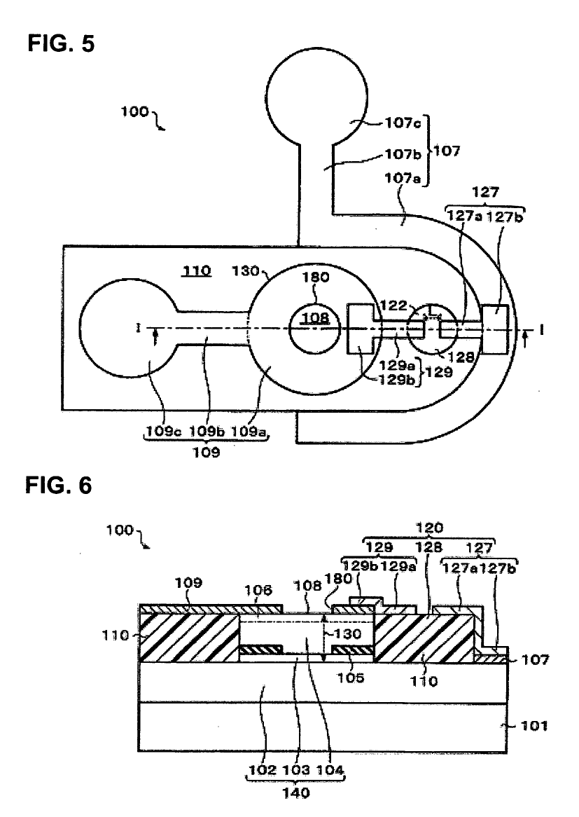

In the example shown in FIG. 1 and FIG. 2, the tips of the protruded sections 127a and 129a of the first and second conductive layers 127 and 129 are pointed. For example, when the tips of the protruded sections 127a and 129a of the first and second conductive layers 127 and 129 are flat (in other words, when the plane configuration of each of the protruded sections 127a and 129a is, for example, rectangular), a uniform electric filed is generated when a voltage is impressed across the first conductive layer 127 and the second conductive layer 129. In contrast, in the example shown in FIG. 1 and FIG. 2, a non-uniform electric field is generated, and an electric filed concentration occurs, when a voltage is impressed across the first conductive layer 127 and the second conductive layer 129. For this reason, in the example shown in FIG. 1 and FIG. 2, the dielectric breakdown voltage of the electrostatic breakdown prevention section 120 is lower, compared to the example shown in FIG. 5. Accordingly, the configuration of the tip of each of the protruded sections 127a and 129a of the first and second conductive layers 127 and 129 is optionally determined so that the dielectric breakdown voltage of the electrostatic breakdown prevention section 120 has a desired value.

Also, in the example shown in FIG. 1 and FIG. 2, the hole 122 is formed in the interlayer dielectric layer 110 on its upper surface side. For example, as shown in FIG. 6, it is possible not to form the hole 122 in the interlayer dielectric layer 110. In this case, the interlayer dielectric layer 110 disposed at the side of the protruded section 127a of the first conductive layer 127 and at the side of the protruded section 129a of the second conductive layer 129 serves as the insulating member 128 in the electrostatic breakdown prevention section 120.

For example, when the hole 122 is formed in the interlayer dielectric layer 110, as in the example shown in FIG. 1 and FIG. 2, the minimum distance along a path defined by the interlayer dielectric layer 110 from the first conductive layer 127 to the second conductive layer 129 can be made longer, compared to the example shown in FIG. 6. More concretely, the minimum distance in the example shown in FIG. 1 and FIG. 2 is a distance from an edge on one side of the hole 122 in a cross-sectional view to an edge on the other side along a path defined by the bottom surface of the hole 122, and the minimum distance in the example shown in FIG. 6 is a distance from the first conductive layer 127 to the second conductive layer 129 along a path defined by the top surface of the interlayer dielectric layer 110. Accordingly, when a voltage is impressed to the electrostatic breakdown prevention section 120, the dielectric breakdown voltage of the interlayer dielectric layer 110 can be made greater due to the fact that the hole 122 is formed in the interlayer dielectric layer 110, compared to the case where the hole 122 is not formed. Further, by adjusting the size and the depth of the hole 122 in the interlayer dielectric layer 110, the dielectric breakdown voltage of the interlayer dielectric layer 110 can be made greater than the dielectric breakdown voltage of the electrostatic breakdown prevention section 120. By this, when a voltage smaller than the dielectric breakdown voltage of the electrostatic breakdown prevention section 120 is impressed to the electrostatic breakdown prevention section 120, a current is prevented from flowing to the electrostatic breakdown prevention section 120 through the interlayer dielectric layer 110. In other words, the electrostatic breakdown prevention section 120 can be operated as designed. Further, because the operation of the electrostatic breakdown prevention section 120 is not influenced by the material of the interlayer dielectric layer 110, an appropriate material can be freely selected for the interlayer dielectric layer 110.

On the other hand, when the hole 122 is not formed in the interlayer dielectric layer 110 as shown in FIG. 6, a minute creeping discharge along a path defined by the interlayer dielectric layer 110 from the first conductive layer 127 to the second conductive layer 129 can be used, compared to the example shown in FIG. 1 and FIG. 2. Accordingly, when the dielectric breakdown voltage of the electrostatic breakdown prevention section 120 is to be maintained to the same level, the distance L between the protruded section 127a of the first conductive layer 127 and the protruded section 129a of the second conductive layer 129 can be made greater in the case where the hole 122 is not formed, compared to the case where the hole 122 is formed. By this, a larger margin can be secured in the forming position of the protruded sections 127a and 129a of the first and second conductive layers 127 and 129.

Also, when a discharge occurs across the first conductive layer 127 and the second conductive layer 129, damage to the interlayer dielectric layer 110 which may be caused by the discharge can be controlled by making the hole 122 in the interlayer dielectric layer 110 larger and deeper.

Further, when a semiconductor material, such as, for example, Si, GaAs or the like is used as the insulating material 128, the semiconductor material may be doped with a dopant (for example, boron or phosphorous in the case of Si), whereby the dielectric breakdown voltage of the electrostatic breakdown prevention section 120 can be lowered. Accordingly, by adjusting the impurity concentration of the semiconductor material, the dielectric breakdown voltage of the electrostatic breakdown prevention section 120 can be set to a desired value.

It is noted that the invention is not limited to the case where the emission section 140 is a surface-emitting type semiconductor laser, but is also applicable to other emission elements (such as, for example, semiconductor emission diodes, and organic LEDs).

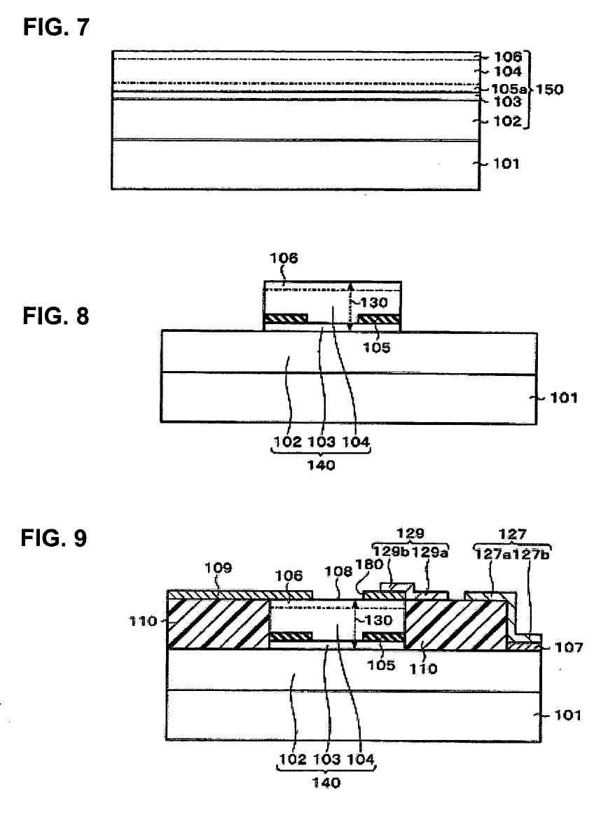

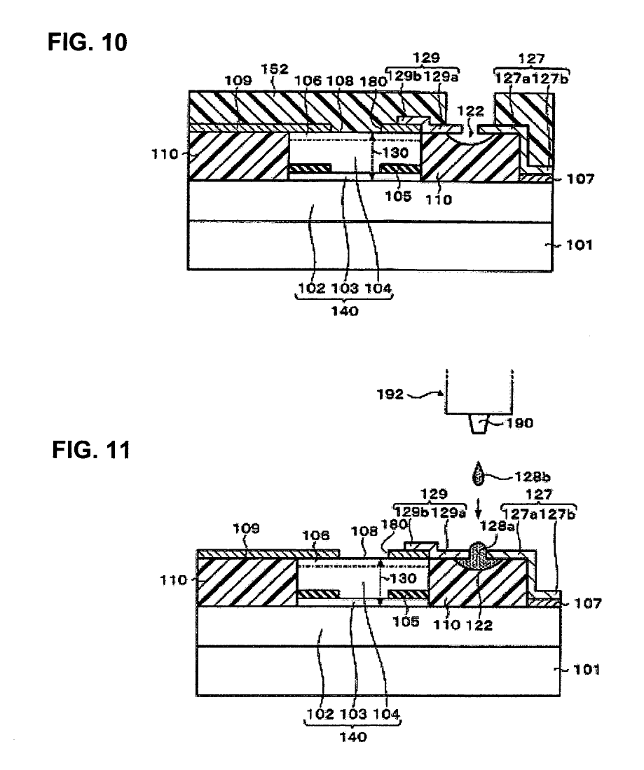

2. Next, an example of a method for manufacturing the optical element 100 in accordance with the present embodiment is described with reference to FIG. 1, FIG. 2, and FIG. 7 through FIG. 11. FIG. 7 through FIG. 11 are cross-sectional views schematically showing a process for manufacturing the optical element 100 in accordance with the present embodiment shown in FIG. 1 and FIG. 2, and correspond to the cross-sectional view shown in FIG. 1, respectively.

(1) First, as shown in FIG. 7, for example, an n-type GaAs substrate is prepared as a substrate 101. Next, a semiconductor multilayer film 150 is formed on the substrate 101 by epitaxial growth while modifying its composition. The semiconductor multilayer film 150 is composed of successively laminated semiconductor layers that compose a first semiconductor layer 102, an active layer 103, and a second semiconductor layer 104. It is noted that, when the second semiconductor layer 104 is grown, at least one layer thereof near the active layer 103 may be formed to be a layer 105a that is later oxidized and becomes an oxidized constricting layer 105. As the layer 105a that becomes to be the oxidized constricting layer 105, for example, an AlGaAs layer with its Al composition being 0.95 or greater can be used. The Al composition of the AlGaAs layer means an aluminum composition to the III-group elements. Also, when the second semiconductor layer 104 is grown, its uppermost layer 106 is formed to become a contact layer.

(2) Next, as shown in FIG. 8, the semiconductor multilayer film 150 is patterned to form the first semiconductor layer 102, the active layer 103, and the second semiconductor layer 104 in a desired configuration. As a result, a columnar section 130 is formed. The semiconductor multilayer film 150 can be patterned by known lithography technique and etching technique.

Next, by placing the substrate 101 on which the columnar section 130 is formed through the aforementioned steps in a water vapor atmosphere at about 400° C., for example, the layer 105a that becomes to be an oxidized constricting layer 105 is oxidized from its side surface, thereby forming the oxidized constricting layer 105. When the emission section 140 having the oxidized constricting layer 105 is driven, electrical current flows only in a portion where the oxidized constricting layer 105 is not formed (a portion that is not oxidized). Accordingly, in the step of forming the oxidized constricting layer 105, the range of the oxidized constricting layer 105 to be formed may be controlled, whereby the current density can be controlled.

(3) Next, as shown in FIG. 9, an interlayer dielectric layer 110 is formed on the first semiconductor layer 102 in a manner to surround the columnar section 130. For example, polyimide resin can be used for the interlayer dielectric layer 110. More concretely, first, a precursor (such as, a polyimide precursor) is coated over the entire surface to cover the columnar section 130 by using, for example, a spin coat method or the like. Next, by using a hot plate or the like, the entire body is heated to thereby remove solvent in the precursor. Then, the entire body is placed in a furnace at, for example, about 350° C. to imidize the precursor, whereby a resin layer (a polyimide resin layer or the like) that is almost completely hardened is formed. Next, by using a CMP or the like, an upper surface of the columnar section 130 is exposed. Then, the resin layer is patterned by known lithography technique and etching technique, to thereby expose a forming region of a first electrode 107 in the upper surface of the semiconductor layer 102. In this manner, the interlayer dielectric layer 110 having a desired configuration can be formed.

Next, first and second electrodes 107 and 109 are formed. These electrodes can be formed in a desired configuration by, for example, a vacuum vapor deposition method and a lift-off method combined. When the second electrode 109 is formed, an opening section 180 is formed over the upper surface of the columnar section 130. Among the upper surface of the second semiconductor layer 104, a portion of the surface that is exposed through the opening section 180 defines an emission surface 108. As the first electrode 107, for example, a laminated film of an alloy of gold (Au) and germanium (Ge), nickel (Ni) and gold (Au) can be used. As the second electrode 109, a laminated film of gold (Au) and an alloy of gold (Au) and zinc (Zn) can be used. It is noted that the order to form the electrodes is not particularly limited.

Next, first and second conductive layers 127 and 129 are formed. These conductive layers can be formed in a desired configuration by, for example, a vacuum vapor deposition method and a lift-off method combined. For example, a high melting-point metal may preferably be used for the first and second conductive layers 127 and 129. By using a high melting-point metal, the first and second conductive layers 127 and 129 can be prevented from melting due to heat generated when a current flows in the electrostatic breakdown prevention section 120. As the high melting-point metal, for example, titanium (Ti), platinum (Pt), rhodium (Rh), tantalum (Ta), tungsten (W), chrome (Cr), palladium (Pd), or an alloy combining any of the aforementioned metals can be used. It is noted that, gold (Au), for example, may also be used for the first and second conductive layers 127 and 129. By forming the first and second conductive layers 127 and 129 with the same material, these conductive layers can be formed in a single manufacturing step. However, the first and second conductive layers 127 and 129 can be formed from different materials. As the first and second conductive layers 127 and 129, for example, a laminated film (for example, a film in which platinum is laminated on titanium) may also be used.

(4) Next, a hole 122 is formed in the interlayer dielectric layer 110 on its upper surface side. First, a mask layer 152 is formed over the entire surface on the upper surface side of the structure formed by the aforementioned steps. As the mask layer 152, for example, resist may be used. Next, the mask layer 152 is patterned by using, for example, known lithography technique and etching technique, whereby the mask layer 152 is formed with an opening in a region where the hole 122 is to be formed.

Next, by using the mask layer 152 as a mask, the interlayer dielectric layer 110 is etched by, for example, a dry etching method. By this, the hole 122 is formed. In this instance, the tips of the protruded sections 127a and 129a of the first and second conductive layers 127 and 129 exposed through the opening section of the mask layer 152 are not etched, and are left suspended in midair. For example, CF₄ plasma may be used for the dry etching method.

(5) Next, as shown in FIG. 11, an insulating member precursor 128a is formed. More concretely, droplets 128b containing the material for the insulating member 128 are discharged in the hole 122 formed in the interlayer dielectric layer 110, thereby forming the insulating member precursor 128a. The droplets 128b are discharged, for example, until the insulating member precursor 128a covers the side faces of the first and second conductive layers 127 and 129. In this instance, the insulating member precursor 128a can be dammed up by the side faces of the first and second conductive layers 127 and 129, and can be dammed up by the edge of the hole 122, as shown in FIG. 2. The insulating member precursor 128a has a property that is settable by application of energy (light, heat or the like). As the insulating member precursor 128a, for example, a precursor of polyimide resin, epoxy resin or the like can be enumerated. Also, the insulating member precursor 128a may be formed from, for example, particles of Si, GaAs, SiO₂, SiN, SiC, AlO₃ or the like dispersed in a solvent, such as, for example, water, propanediol, butyl acetate, mesitylene, decalin, or the like.

As the droplet discharging method for discharging the droplets 128b, for example, a dispenser method and an ink jet method can be enumerated. The dispenser method is a common method for discharging droplets, and is effective in discharging the droplets 128b in a relatively wide area. The ink jet method is a method for discharging droplets by using an ink jet head 192 for droplet ejection, and can highly accurately control the droplet discharge location and the amount of each droplet. For this reason, the insulating member 128 with a minute structure can be manufactured.

Alignment between the position of an ink jet nozzle 190 of the ink jet head 192 and the discharge position of the droplet 128b is performed by using a known image recognition technology that may be used in an exposure step and an examination step in an ordinary process for manufacturing semiconductor integrated circuits. For example, the position of the ink jet nozzle 190 of the ink jet head 192 and the hole 122 in the interlayer dielectric layer 110 are aligned by image recognition. After they are aligned, the voltage to be applied to the ink jet head 192 is controlled, and the droplet 128b is discharged.

For example, even when there are some differences in the discharge angle of the droplets 128b ejected from the ink jet nozzle 190, the insulating member precursor 128a wets and spreads within the hole 122 if the impact positions of the droplets 128b are inside the hole 122 in the interlayer dielectric layer 110, and these positions are automatically corrected.

(6) Next, as shown in FIG. 1 and FIG. 2, the insulating member precursor 128a is hardened, thereby forming the insulating member 128. More concretely, energy (light, heat or the like) is applied to the insulating member precursor 128a. When the insulating member precursor 128a is hardened, an appropriate method is selected according to the kind of the material of the insulating member precursor 128a. More concretely, for example, application of heat energy, or irradiation of ultraviolet ray, laser light or the like may be conducted.

It is noted that the process described above concerns an example where the insulating member 128 is formed by a droplet discharge method. However, the insulating member 128 may be formed by, for example, a CVD method or the like, and then patterned. Also, when a gas such as air is used as the insulating member 128, as shown in FIG. 4, for example, the step of forming the insulating member precursor 128a and the step of hardening the insulating member precursor 128a described above can be omitted.

By the steps described above, the optical element 100 in accordance with the present embodiment shown in FIG. 1 and FIG. 2 is obtained.

3. Even when a voltage that may cause an electrostatic breakdown is impressed to the emission section 140, a current flows to the electrostatic breakdown prevention section 120 that is connected in parallel with the emission section 140. By this, the electrostatic breakdown voltage resistance of the optical element 100 can be considerably improved. Accordingly, an electrostatic breakdown of the device by static electricity in a mounting process or the like can be prevented, which results in excellent handling, and improves the reliability.

Also, according to the optical element 100 in accordance with the present embodiment, the first conductive layer 127 and the second conductive layer 129 can be more freely arranged. Accordingly, for example, compared to the case where the electrostatic breakdown prevention section 120 is formed by laminating the first conductive layer 127, the insulating member 128 and the second conductive layer 129 in a thickness direction (hereafter referred to as a “thickness direction lamination example”), the distance between the first conductive layer 127 and the second conductive layer 129 can be readily adjusted. In other words, the dielectric breakdown voltage of the electrostatic breakdown prevention section 120 formed between the first conductive layer 127 and the second conductive layer 129 can be readily adjusted, whereby the degree of freedom in design can be improved.

Also, according to the optical element 100 in accordance with the present embodiment, the area of a portion of the first conductive layer 127 (the side face of the tip of the protruded section 127a of the first conductive layer 127) opposing to the second conductive layer 129, and the area of a portion of the second conductive layer 129 (the side face of the tip of the protruded section 129a of the second conductive layer 129) opposing to the first conductive layer 127 can be readily made smaller, for example, compared to the thickness direction lamination example. Accordingly, by the optical element 100 in accordance with the present embodiment, the capacity of the electrostatic breakdown prevention section 120 can be readily made smaller, and therefore the emission section 140 can be driven at high speed.

Also, according to the optical element 100 in accordance with the present embodiment, the area of portions of the first and second conductive layers 127 and 129 which are formed on the interlayer dielectric layer 110 can be freely set. Accordingly, for example, by reducing the area, the parasitic capacitance formed by the first and second conductive layers 127 and 129, the interlayer dielectric layer 110, and for example, the first semiconductor layer 102 can be made smaller. As a result, the emission section 140 can be driven at high speed.

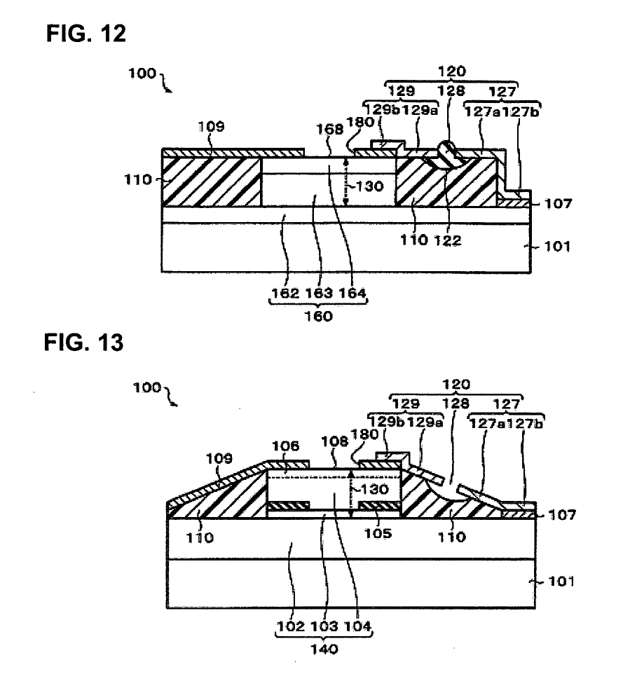

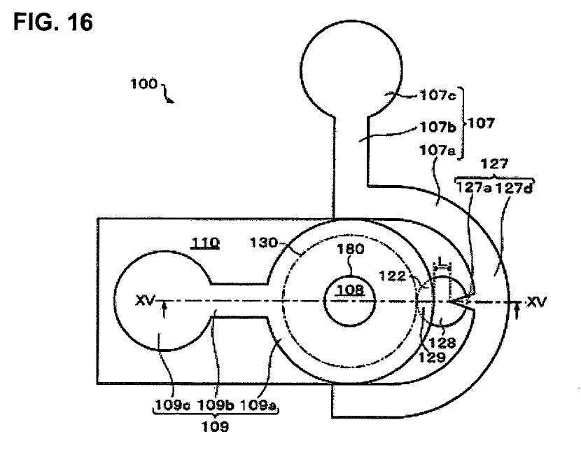

4. Next, modification examples of the optical element 100 in accordance with embodiments are described with reference to the accompanying drawings. It is noted that features different from the optical element 100 described above and shown in FIG. 1 and FIG. 2 are mainly described, and descriptions of similar features are omitted. FIGS. 12-14 are cross-sectional views schematically showing examples of the modification examples of the optical element 100, FIG. 15 is a cross-sectional view taken along a line XV-XV of FIG. 16, and FIGS. 16-18 are plan views schematically showing examples of the modification examples of the optical element 100.

For example, as shown in FIG. 12, a photodetecting section 160 may be formed instead of the emission section 140. The photodetecting section 160 may function, for example, as a pin type photodiode. The photodetecting section 160 may include a first semiconductor layer 162 of a first conductivity type (for example, n-type), a photoabsorption layer 163 formed on the first semiconductor layer 162, and a second semiconductor layer 164 of a second conductivity type (for example, p-type) formed on the photoabsorption layer 163. The first semiconductor layer 162 may be formed from, for example, an n-type GaAs layer, the photoabsorption layer 163 may be formed from, for example, a GaAs layer that is not doped with an impurity, and the second semiconductor layer 164 may be formed from, for example, a p-type GaAs layer. In this case, instead of the emission surface 108, a light incidence surface 168 is formed. It is noted that photodetecting elements to which the invention is applicable include pn-type photodiodes, avalanche type photodiodes, MSM type photodiodes and the like.

Also, the present invention is applicable, for example, to a laminated structure in which the emission section 140 and the photodetecting section 160 are laminated (for example, a surface-emitting type semiconductor laser with a monitoring photodiode).

Further, for example, as shown in FIG. 13, the upper surface of the interlayer dielectric layer 110 can be sloped. In the illustrated example, the interlayer dielectric layer 110 is formed to have an upper surface higher on the side of the columnar section 130. By this, compared to the example shown in FIG. 1 and FIG. 2, it is possible to increase the area where the protruded section 127a of the first conductive layer 127 and the protruded section 129a of the second conductive layer 129 can be formed, without increasing the element area as viewed in a plan view. Accordingly, the degree of freedom in design can be improved. It is noted that the upper surface of the interlayer dielectric layer 110 can be sloped by, for example, enhancing the adhesion between the side surface of the columnar section 130 and the interlayer dielectric layer 110.

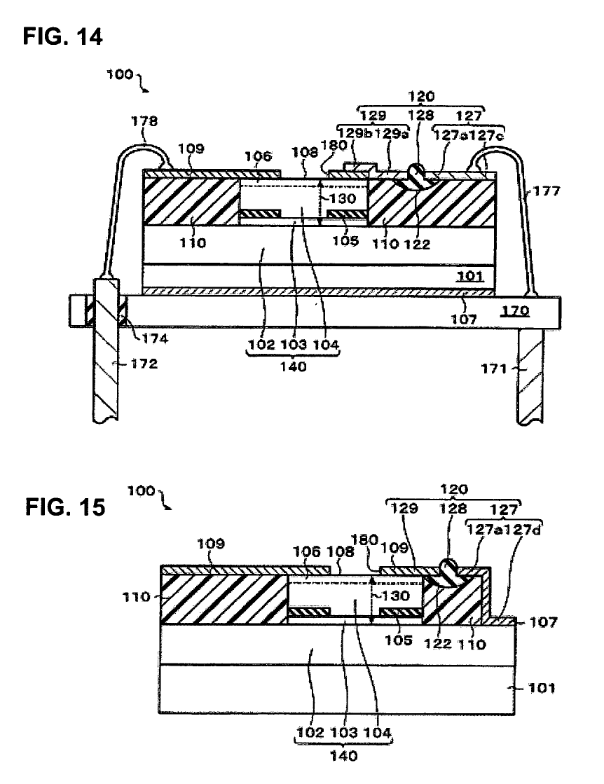

Also, as shown in FIG. 14, for example, the first electrode 107 can be formed on the back surface of the substrate 101. In this case, because the first electrode 107 can be formed over the entire back surface of the substrate 101, the resistance between the first electrode 107 and the second electrode 109 can be reduced, compared to the example shown in FIG. 1 and FIG. 2 where the first electrode 107 is formed on the first semiconductor layer 102. For example, as shown in FIG. 14, the optical element 100 can be mounted on a mounting member (stem) 170. The first conductive layer 127 includes a protruded section 127a and a pad section 127c. The mounting member 170 and the pad section 127c of the first conductive layer 127 may be connected to each other by, for example, a first bonding wire 177. By this, the first conductive layer 127 is electrically connected to the first semiconductor layer 102 through the first bonding wire 177, the mounting member 170, the first electrode 107 and the substrate 101. The mounting member 170 is provided with a first lead terminal 171 and a second lead terminal 172. The second lead terminal 172 penetrates the mounting member 170. An upper surface of the second lead terminal 172 is connected to the second electrode 109 by a second bonding wire 178. The second lead terminal 172 is electrically isolated from the mounting member 170 by an insulating layer 174.

Furthermore, for example, as shown in FIG. 15 and FIG. 16, the first conductive layer 127 can serve as the first electrode 107, and the second conductive layer 129 can serve as the second electrode 109. In other words, the first and second conductive layers 127 and 129 can be served as electrodes for driving the emission section 140. By this, the process for manufacturing the optical element 100 can be simplified. The first conductive layer 127 includes a protruded section 127a and a contact section 127d. The contact section 127d of the first conductive layer 127 also serves as the contact section 107a of the first electrode 107. Also, for example, as shown in FIG. 15 and FIG. 16, the first conductive layer 127 may have the protruded section 127a, and the second conductive layer 129 may not be provided with a protruded section. Similarly, although not illustrated, the second conductive layer 129 may be provided with a protruded section 129a, and the first conductive layer 127 may not be provided with a protruded section. In other words, at least one of the first conductive layer 127 and the second conductive layer 129 has a protruded section. This similarly applies to all of the examples of the optical element 100 described above.

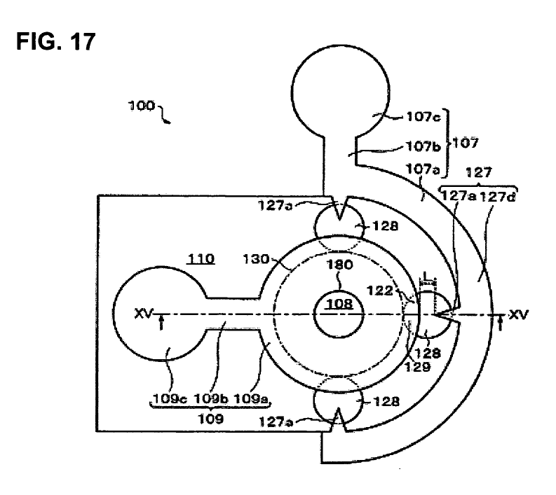

Also, for example, as shown in FIG. 17, the first conductive layer 127 may be formed with plural protruded sections 127a, and plural insulating members 128 may be provided. In the example shown in FIG. 17, the protruded sections 127a of the first conductive layer 127 and the insulating members 128 are formed in three sets. Two of the protruded sections 127a may protrude, for example, from end sections of the contact section 107a of the first electrode 107 toward a contact section 109a of the second electrode 109. By forming the plural protruded sections 127a and insulating members 128, the reliability of the electrostatic breakdown prevention section 120 can be improved. For example, when any of the protruded sections 127a is not formed in a desired configuration in the step of patterning the first conductive layer 127, but the remaining protruded section 127a is formed in a desired configuration, the reliability of the electrostatic breakdown prevention section 120 can be secured. This similarly applies to the protruded section 129a of the second conductive layer 129, and the second conductive layer 129 can be formed with plural protruded sections 129a.

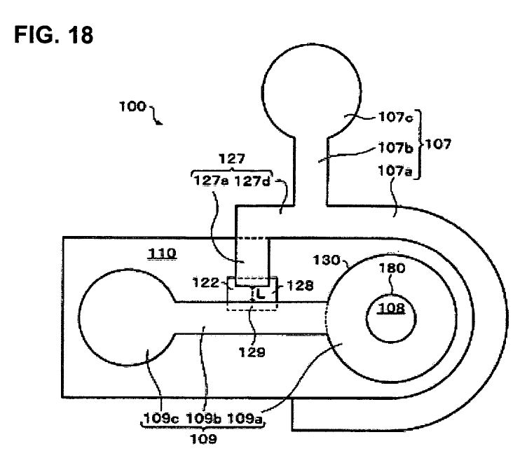

Moreover, for example, as shown in FIG. 18, the second conductive layer 129 can also serve as the lead-out section 109b of the second electrode 109. The protruded section 127a of the first conductive layer 127 has a plane configuration that is, for example, a rectangular shape shown in FIG. 18. The protruded section 127a protrudes, as shown in FIG. 18, for example, from an end section of the contact section 107a of the first electrode 107 toward the lead-out section 109b of the second electrode 109. The protruded section 127a opposes to the lead-out section 109b of the second electrode 109 through the insulating member 128. The hole 122 has a plane configuration that may be, for example, a rectangular shape shown in FIG. 18.

It is noted that the modified examples described above are only examples, and the invention is not limited to these examples.

Although the embodiments of the invention are described above in detail, it should be readily understood by a person having ordinary skill in the art that many modifications can be made without departing in substance from the novelty and effects of the invention. Accordingly, such modified examples should be included in the scope of the invention.

For example, in the optical elements 100 in accordance with the embodiments described above, the description is made as to the case where one columnar section 130 is provided. However, the mode of the invention shall not be harmed even when a plurality of columnar sections 130 are provided, or when the columnar section 130 is not formed in the step of patterning the semiconductor multilayer film 150. Also, when a plurality of optical elements 100 are formed in an array, similar actions and effects shall be achieved. Furthermore, it should be noted that, for example, interchanging the p-type and n-type characteristics of each of the semiconductor layers in the above described embodiments does not deviate from the subject matter of the invention. Furthermore, for example, when an epitaxial lift off (ELO) method is used, the substrate 101 of the optical element 100 can be separated. In other words, the optical element 100 can be provided without the substrate 101.

What is claimed is:

1. An optical element comprising:
an emission section including a first semiconductor layer of a first conductivity type, an active layer formed above the first semiconductor layer and a second semiconductor layer of a second conductivity type formed above the active layer;
an interlayer dielectric layer; and
an electrostatic breakdown prevention section including a first conductive layer formed above the interlayer dielectric layer, a second conductive layer formed above the interlayer dielectric layer, and an insulating member formed between the first conductive layer and the second conductive layer, and at a side of the first conductive layer and at a side of the second conductive layer,
wherein the first conductive layer is electrically connected to the first semiconductor layer,
the second conductive layer is electrically connected to the second semiconductor layer,
at least one of the first conductive layer and the second conductive layer has a protruded section,
the emission section and the electrostatic breakdown prevention section are electrically connected in parallel with each other, and
a dielectric breakdown voltage of the electrostatic breakdown prevention section is greater than a drive voltage of the emission section and smaller than an electrostatic breakdown voltage of the emission section.

2. An optical element according to claim 1, wherein the electrostatic breakdown voltage of the emission section concerns a reverse bias.

3. An optical element according to claim 1, wherein the first conductive layer and the second conductive layer are electrodes for driving the emission section.

4. An optical element according to claim 1, wherein the emission section functions as a surface-emitting type semiconductor laser, and the first semiconductor layer and the second semiconductor layer are mirrors.

5. An optical element comprising:
a photodetection section including a first semiconductor layer of a first conductivity type, a photoabsorption layer formed above the first semiconductor layer and a second semiconductor layer of a second conductivity type formed above the photoabsorption layer;
an interlayer dielectric layer; and
an electrostatic breakdown prevention section including a first conductive layer formed above the interlayer dielectric layer, a second conductive layer formed above the interlayer dielectric layer, and an insulating member formed between the first conductive layer and the second conductive layer, and at a side of the first conductive layer and at a side of the second conductive layer,
wherein the first conductive layer is electrically connected to the first semiconductor layer,
the second conductive layer is electrically connected to the second semiconductor layer,
at least one of the first conductive layer and the second conductive layer has a protruded section,
the photodetection section and the electrostatic breakdown prevention section are electrically connected in parallel with each other, and
a dielectric breakdown voltage of the electrostatic breakdown prevention section is greater than a drive voltage of the photodetection section and smaller than an electrostatic breakdown voltage of the photodetection section.

6. An optical element according to claim 1, comprising a substrate, wherein the first semiconductor layer and the interlayer dielectric layer are formed above the substrate.

7. An optical element according to claim 1, comprising a first electrode formed between the first semiconductor layer and the first conductive layer, and a second electrode formed between the second semiconductor layer and the second conductive layer.

8. An optical element according to claim 1, wherein the protruded section has a pointed tip.

9. An optical element according to claim 1, wherein the protruded section has a flat tip.

10. An optical element according to claim 1, wherein the interlayer dielectric layer defines a hole, and the protruded section has a tip that is formed above the hole, and not in contact with the interlayer dielectric layer.

11. An optical element according to claim 1, wherein the insulating member has an upper surface that is a convex curved surface.

12. A method for manufacturing an optical element, comprising the steps of:
forming a semiconductor multilayer film, including forming a first semiconductor layer of a first conductivity type above a substrate, forming an active layer above the first semiconductor layer, and forming a second semiconductor layer of a second conductivity type above the active layer;
patterning the semiconductor multilayer film to form an emission section that includes the first semiconductor layer, the active layer and the second semiconductor layer;
forming an interlayer dielectric layer above the substrate;
forming a first conductive layer above the interlayer dielectric layer;
forming a second conductive layer above the interlayer dielectric layer; and
forming an insulating member between the first conductive layer and the second conductive layer, and at a side of the first conductive layer and at a side of the second conductive layer,
wherein the first conductive layer is arranged to electrically connect to the first semiconductor layer,
the second conductive layer is arranged to electrically connect to the second semiconductor layer,
at least one of the first conductive layer and the second conductive layer is formed to have a protruded section,
an electrostatic breakdown prevention section including the first conductive layer, the second conductive layer and the insulating member is arranged to electrically connect in parallel with the emission section, and
a dielectric breakdown voltage of the electrostatic breakdown prevention section is set to be greater than a drive voltage of the emission section and smaller than an electrostatic breakdown voltage of the emission section.

13. A method for manufacturing an optical element according to claim 12, wherein the insulating member is formed by using a droplet discharge method.

14. A method for manufacturing an optical element according to claim 12, comprising forming a hole in the interlayer dielectric layer by etching after at least one of the step of forming the first conductive layer and the step of forming the second conductive layer, wherein a tip of the protruded section is formed above the hole so as not to contact the interlayer dielectric layer.

15. An optical element according to claim 5, comprising a substrate, wherein the first semiconductor layer and the interlayer dielectric layer are formed above the substrate.

16. An optical element according to claim 5, comprising a first electrode formed between the first semiconductor layer and the first conductive layer, and a second electrode formed between the second semiconductor layer and the second conductive layer.

17. An optical element according to claim 5, wherein the protruded section has a pointed tip.

18. An optical element according to claim 5, wherein the protruded section has a flat tip.

19. An optical element according to claim 5, wherein the interlayer dielectric layer defines a hole, and the protruded section has a tip that is formed above the hole, and not in contact with the interlayer dielectric layer.

20. An optical element according to claim 5, wherein the insulating member has an upper surface that is a convex curved surface.
